(19) United States
(12) Patent Application Publication
(10) Pub. No.: US 2015/0357537 A1
(43) Pub. Date: Dec. 10, 2015

(54) SUBSTRATE STRUCTURE APPLICABLE TO VERTICAL LIGHT EMITTING ELEMENT AND VERTICAL LIGHT EMITTING ELEMENT THEREOF

(71) Applicant: PHECDA TECHNOLOGY CO., LTD., Taipei (TW)

(72) Inventors: Kuang-Ning KUANG, Zhubei City (TW); Chi-wei LEE, Zhubei City (TW); Jian-Jhih CHEN, Zhubei City (TW)

(21) Appl. No.: 14/473,962

(22) Filed: Aug. 29, 2014

(30) Foreign Application Priority Data
Jun. 9, 2014 (TW) 103210136

(51) Int. Cl. H01L 33/60; H01L 33/62

(52) U.S. Cl. CPC H01L 33/60; H01L 33/62

(57) ABSTRACT

The present invention discloses a substrate structure applicable to a vertical light emitting element and a vertical light emitting element thereof. The substrate structure comprises a transparent substrate and a reflective layer, and the reflective layer is used to improve a focus of a yellow light manufacturing process. The technique is applicable to PSS substrate and the substrate structure is used to produce the vertical light emitting element to increase the light emitting efficiency.

### CROSS-REFERENCE TO RELATED APPLICATION

This application claims priority from Taiwan Patent Application No. 103210136, filed on Jun. 9, 2014, in the Taiwan Intellectual Property Office, the content of which are hereby incorporated by reference in their entirety for all purposes.

### BACKGROUND OF THE INVENTION

1. Field of the Invention

The present invention discloses a substrate structure, in particular with respect to a substrate structure applicable to light emitting element.

2. Description of the Related Art

Two electrode layers of a vertical light emitting element are respectively disposed at two sides of a light emitting layer, such that almost the currents are able to vertically flow through the light emitting layer, and only a few currents flow transversely. Therefore, it can improve the currents distribution of the plane structure so as to increase light emitting efficiency, and also resolve the shading of electrode to promote the light emitting area of LED.

Using the microstructure of the pattern sapphire substrate (PSS) to increase the light extraction enhancement is the mainstream of the industry, however, while a transparent substrate is used to focus, the light source will directly penetrate therethrough which leads to an incorrect focus, resulting that the PSS is enable to be used in the manufacturing process of the vertical light emitting element, and the application of the PSS is therefore restricted.

According to the preceding description, the inventor of the present invention designs a substrate structure which aims at improving the shortcomings of the current technique so as to increase the industrial applicability.

### SUMMARY OF THE INVENTION

In view of the known technical problems, the purpose of the present invention is to provide a substrate structure which may comprise a reflective disposed on upper or lower surface of a transparent substrate for contributing to a focus of a yellow light manufacturing process.

In view of the known technical problems, the purpose of the present invention is to provide a substrate structure which is applicable to apply the pattern sapphire substrate to the manufacturing process of a vertical light emitting element so as to expand the application of PSS.

According to the purpose of the present invention, it provides a substrate structure which may comprise a transparent substrate and a reflective layer, and the transparent substrate may comprise an upper surface and a lower surface, the reflective layer may be disposed on the upper or the lower surface, and the reflective layer may assist a yellow light manufacturing process in focusing.

Preferably, the yellow light manufacturing process may be conducted through the upper surface.

Preferably, the reflective layer may be removed when the yellow light manufacturing process is conducted.

Preferably, removal of the reflective layer may comprise mechanism removal, chemical removal or combination thereof.

Preferably, the transparent substrate may comprise a transparent sapphire substrate, a glass substrate or a crystal substrate.

Preferably, the transparent substrate may be a pattern sapphire substrate.

Preferably, the upper surface or the lower surface may further comprise a plurality of microstructures for increasing light extraction enhancement.

In accordance with the aforementioned purpose, the present invention further provides a vertical light emitting element which may comprise a transparent substrate and a vertical light emitting element structure. The transparent substrate may comprise an upper surface and a lower surface; and a vertical light emitting element structure may be disposed on the transparent substrate, and may comprise: a first ohmic electrode, a first semiconductor, a light emitting layer, a second semiconductor and a second ohmic electrode. The first ohmic electrode may be disposed on the upper surface; the first semiconductor layer may be disposed on the first ohmic electrode; the light emitting layer may be disposed on the semiconductor layer; the second semiconductor layer may be disposed on the light emitting layer; and the second ohmic electrode may contact with the second semiconductor.

Preferably, the transparent substrate may further comprise a reflective layer disposed on the upper surface or the lower surface to assist a yellow light manufacturing process in focusing, and the reflective layer may be removed when the yellow light manufacturing process is conducted.

Preferably, removal of the reflective layer may comprise mechanism removal, chemical removal or combination thereof.

Preferably, the transparent substrate may be a pattern sapphire substrate.

Preferably, the transparent substrate may comprise a transparent sapphire substrate, a glass substrate or a crystal substrate.

Preferably, the upper surface or the lower surface may further comprise a plurality of microstructures for increasing light extraction enhancement.

Preferably, the first and the second ohmic electrodes may be selected from at least one alloy or multilayer film consisted of an oxide or a nitride comprising a group of nickel, lead, cobalt, iron, titanium, copper, rhodium, gold, ruthenium, tungsten, zirconium, molybdenum, tantalum, silver.

The primary purpose of the present invention is to provide a substrate structure applicable to a vertical light emitting element and a vertical light emitting element thereof which has one or more following advantages:

1. Breakthrough of the restriction against the manufacturing process: by disposing a reflective layer on upper or lower surface of a transparent substrate and using the reflective to assist the yellow light manufacturing process in focusing, the incorrect focus of the transparent substrate is thereby able to be resolved.

2. Expansion of the application: by disposing a reflective layer on upper or lower surface of a transparent substrate, the application of PSS is able to be expanded, and by the microstructure on the surface of the PSS, the efficiency of light extraction enhancement is able to be increased and the illumination is thereby able to be promoted as well.

Hereinafter, embodiments of the present invention will be described in detail with reference to the accompanying drawings so that those skilled in the art to which the present invention pertains can realize the present invention.

### BRIEF DESCRIPTION OF THE DRAWINGS

FIG. 1 is a schematic diagram of a substrate structure of the resent invention.

FIG. 2 is a schematic diagram of a vertical light emitting element of the present invention.

### DETAILED DESCRIPTION OF THE PREFERRED EMBODIMENTS

Hereinafter, embodiments of the present invention will be described in detail with reference to the accompanying drawings so that those skilled in the art to which the present invention pertains can realize the present invention. As those skilled in the art would realize, the described embodiments may be modified in various different ways, all without departing from the spirit or scope of the present invention.

The exemplary embodiments of the present invention will be understood more fully from the detailed description given below and from the accompanying drawings of various embodiments of the invention, which, however, should not be taken to limit the invention to the specific embodiments, but are for explanation and understanding only.

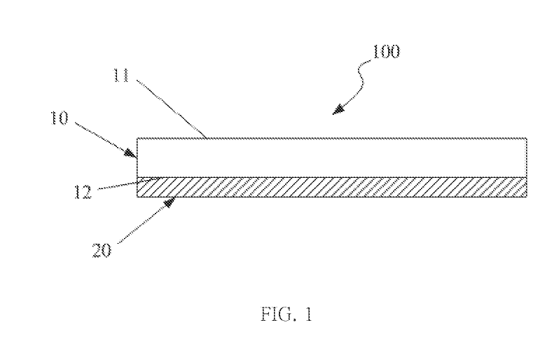

Please refer to FIG. 1 which is a schematic diagram of a substrate structure of the resent invention. As the FIG. shows, a transparent substrate 100 comprises a transparent substrate 10 and a reflective 20. The transparent substrate 10 has an upper surface 11 and a lower surface 12; materials of the transparent substrate 10 comprise a transparent sapphire substrate, a glass substrate or a crystal substrate, but it shall not subject to this restriction. In applicability, the transparent substrate 10 is further a pattern sapphire substrate (PSS), and microstructures on the surface of the transparent substrate 10 are used to increase light extraction enhancement.

The reflective layer 20 is disposed on the upper 11 or the lower 12 surface of the transparent substrate 10, the reflective layer 20 is used to assist a yellow light manufacturing process in focusing, and the incorrect focus of the transparent substrate 10 is resolved so that the current manufacturing process is thereby improved. In applicability, the reflective layer 20 is not restricted by any materials; it only needs to satisfy with the demand of the steps for assisting the yellow light manufacturing process in focusing.

For example, when the lower surface 12 of the transparent substrate 10 is disposed with the reflective layer 20 to form the substrate structure 100, the yellow light manufacturing process is conducted on the upper surface 11 of the transparent substrate 10 to proceed to focus, and the reflective layer 20 is removed by mechanism removal, chemical removal or combination thereof after the yellow light manufacturing process is conducted, but is shall not subject to this restriction.

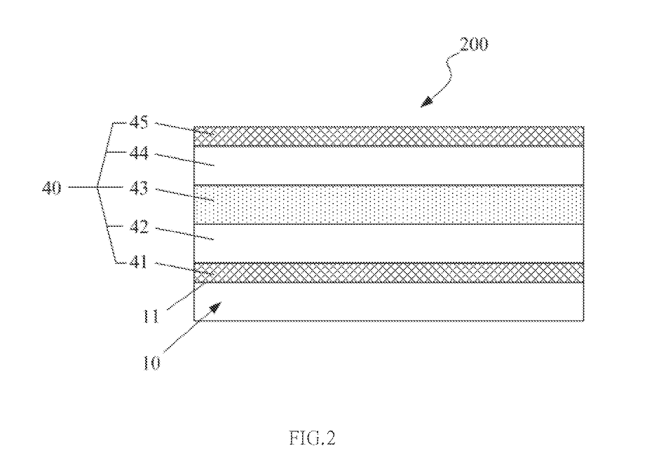

Please refer to FIG. 2 which is a schematic diagram of a vertical light emitting element of the present invention. The present invention further provides concept concerning using the transparent substrate 100 to perform the manufacturing process of a vertical light emitting element 200. As can be seen from the FIG., the vertical light emitting element 200 is to manufacture a vertical light emitting element structure 40 on the transparent structure 10, and a first ohmic electrode 41, a first semiconductor layer 42, a light emitting layer 43, a second semiconductor layer 44 and a second ohmic electrode 42 are orderly stacked on the vertical light emitting element structure 40.

In applicability, the reflective layer 20 is disposed on the transparent substrate 10 to assist the yellow light manufacturing process in focusing, and the reflective layer 20 is removed by mechanism removal, chemical removal or combination thereof when the steps of focusing is conducted; accordingly, the aforementioned structure is orderly stacked on the upper surface 11 of the transparent substrate 10 to form the vertical light emitting element 200.

Wherein, the first semiconductor layer 42, the light emitting layer 43 and the second semiconductor layer 44 are the III-V group semiconductor, such as gallium nitride group semiconductor. As to the first ohmic electrode 41 and the second ohmic electrode 45, they are selected from at least one alloy or multilayer film consisted of an oxide or a nitride comprising a group of nickel, lead, cobalt, iron, titanium, copper, rhodium, gold, ruthenium, tungsten, zirconium, molybdenum, tantalum, silver.

In conclusion, a substrate structure applicable to a vertical light emitting element and a vertical light emitting element thereof of the present invention is to improve the problem of the incorrect focus of the yellow light manufacturing process by disposing a reflective layer on an upper surface or a lower surface of a transparent substrate. The concept is able to to promote the precision of focusing effectively, and by means of the technique, it can manufacture the vertical light emitting element on the pattern sapphire substrate having microstructure surface thereon; in the meanwhile, it can use the microstructure surface structure of the pattern sapphire substrate and the vertical light emitting element which is characterized of better illumination to increase the light emitting efficiency of LED structure so as to expand the application of the pattern sapphire substrate.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A substrate structure applicable to a vertical light emitting element, comprising:
a transparent substrate comprising an upper surface and a lower surface; and
a reflective layer disposed on the upper surface or the lower surface, and the reflective layer assisting a yellow light manufacturing process in focusing.

2. The substrate structure applicable to a vertical light emitting element of claim 1, wherein the yellow light manufacturing process is conducted through the upper surface.

3. The substrate structure applicable to a vertical light emitting element of claim 1, wherein the reflective layer is removed when the yellow light manufacturing process is conducted.

4. The substrate structure applicable to a vertical light emitting element of claim 1, wherein removal of the reflective layer comprises mechanism removal, chemical removal or combination thereof.

5. The substrate structure applicable to a vertical light emitting element of claim 1, wherein the transparent substrate comprises a transparent sapphire substrate, a glass substrate or a crystal substrate.

6. The substrate structure applicable to a vertical light emitting element of claim 1, wherein the transparent substrate is a pattern sapphire substrate.

7. The substrate structure applicable to a vertical light emitting element of claim 1, wherein the upper surface or the lower surface further comprises a plurality of microstructures for increasing light extraction enhancement.

8. A vertical light emitting element, comprising:
a transparent substrate comprising an upper surface and a lower surface; and
a vertical light emitting element structure disposed on the transparent substrate, and comprising:
a first ohmic electrode disposed on the upper surface;
a first semiconductor layer disposed on the first ohmic electrode;
a light emitting layer disposed on the semiconductor layer;
a second semiconductor layer disposed on the light emitting layer; and
a second ohmic electrode contacting with the second semiconductor.

9. The vertical light emitting element of claim 8, wherein the transparent substrate further comprises a reflective layer disposed on the upper surface or the lower surface to assist a yellow light manufacturing process in focusing, and the reflective layer is removed when the yellow light manufacturing process is conducted.

10. The vertical light emitting element of claim 9, wherein removal of the reflective layer comprises mechanism removal, chemical removal or combination thereof.

11. The vertical light emitting element of claim 8, wherein the transparent substrate is a pattern sapphire substrate.

12. The vertical light emitting element of claim 8, wherein the transparent substrate comprises a transparent sapphire substrate, a glass substrate or a crystal substrate.

13. The vertical light emitting element of claim 8, wherein the upper surface or the lower surface further comprises a plurality of microstructures for increasing light extraction enhancement.

14. The vertical light emitting element of claim 8, wherein the first and the second ohmic electrodes are selected from at least one alloy or multilayer film consisted of an oxide or a nitride comprising a group of nickel, lead, cobalt, iron, titanium, copper, rhodium, gold, ruthenium, tungsten, zirconium, molybdenum, tantalum, silver.
